(19) United States
(12) Patent Application Publication
(10) Pub. No.: US 2025/0107403 A1
(43) Pub. Date: Mar. 27, 2025

(54) DISPLAY PANEL AND DISPLAY DEVICE

(71) Applicants: VISIONOX TECHNOLOGY INC., Jiangsu (CN); HEFEI VISIONOX TECHNOLOGY CO., LTD., Hefei (CN)

(72) Inventors: Chao Chi PENG, Jiangsu (CN); Haohan ZHANG, Jiangsu (CN); Zhengkui DONG, Jiangsu (CN); Yiming XIAO, Jiangsu (CN)

(73) Assignees: VISIONOX TECHNOLOGY INC., Jiangsu (CN); HEFEI VISIONOX TECHNOLOGY CO., LTD., Hefei (CN)

(21) Appl. No.: 18/889,499

(22) Filed: Sep. 19, 2024

(30) Foreign Application Priority Data
Sep. 25, 2023 (CN) 202311243165.7
Jul. 16, 2024 (CN) 202410950469.5

(51) Int. Cl. H10K 59/80; H10K 59/122; H10K 59/131

(52) U.S. Cl. CPC H10K 59/873; H10K 59/122; H10K 59/131

(57) ABSTRACT

A display panel and a display device. The display panel includes: a substrate; a plurality of sub-pixels arranged on the substrate at intervals; an isolating structure, disposed between at least some of adjacent sub-pixels; and a plurality of sub-encapsulation parts arranged on sides of corresponding sub-pixels away from the substrate, respectively. At least one groove is formed on a top side of the isolating structure away from the substrate, and each groove has a groove cavity proximate to the substrate and an opening away from the substrate. An orthographic projection of the opening projected on the substrate is within an orthographic projection of the groove cavity projected on the substrate. Each sub-encapsulation part corresponding to at least one sub-pixel adjacent to each groove covers a side surface of the isolating structure proximate to the at least one sub-pixel.

### CROSS-REFERENCE TO RELATED APPLICATION

This application claims priorities to Chinese Patent Application No. 2023112431657, entitled “DISPLAY PANEL AND DISPLAY DEVICE”, filed on Sep. 25, 2023, and Chinese Patent Application No. 202410950469.5, entitled “DISPLAY PANEL AND DISPLAY DEVICE”, filed on Jul. 16, 2024, which are incorporated herein by reference in their entireties

### TECHNICAL FIELD

This application relates to the field of display technologies, and in particular, to a display panel and a display device.

### BACKGROUND

An organic light emitting diode (OLED) display technology is considered as a new type of flat panel display technology with most potential of a next generation. Compared with the liquid crystal display technology, the OLED display technology has advantages of low energy consumption, low cost, self-luminous, wide viewing angle, and fast response speed. However, the existing OLED display panel has a problem of poor reliability.

### SUMMARY

Therefore, it is necessary to provide a display panel and a display device that can improve reliability.

In a first aspect, an embodiment of this application provides a display panel. The display panel includes: a substrate; a plurality of sub-pixels arranged on the substrate at intervals; an isolating structure, disposed between at least some of adjacent sub-pixels; and a plurality of sub-encapsulation parts arranged on sides of corresponding sub-pixels away from the substrate, respectively.

At least one groove is formed on a top side of the isolating structure away from the substrate, and each groove has a groove cavity proximate to the substrate and an opening away from the substrate; an orthographic projection of the opening projected on the substrate is within an orthographic projection of the groove cavity projected on the substrate.

Each sub-encapsulation part corresponding to at least one sub-pixel adjacent to each groove covers a side surface of the isolating structure proximate to the at least one sub-pixel, a top side of the isolating structure away from the substrate, and at least part of a groove wall of the groove.

According to the display panel provided in this embodiment of this application, the groove is formed on the top side of the isolating structure away from the substrate, and the sub-encapsulation part extends from the side surface of the isolating structure to cover the top side of the isolating structure away from the substrate, and extends to at least part of a groove wall of the groove. In this way, on one hand, the coverage area of the sub-encapsulation part on the isolating structure is increased, so that a peeling path of the sub-encapsulation part is prolonged, and the encapsulation performance of the sub-encapsulation part is improved. On the other hand, because the sub-encapsulation part extends to the groove wall of the groove, the cavity between the sub-encapsulation part and the isolating structure is eliminated, and a risk that the peeling occurs between the sub-encapsulation part and the top side of the isolating structure away from the substrate is reduced, thereby improving the encapsulation performance of the sub-encapsulation part. In still another aspect, the sub-encapsulation part extends to a groove wall of the groove, and even if the peeling occurs, the groove wall of the groove may play a function of blocking, thereby protecting the sub-encapsulation part, and reducing a risk of the peeling occurring between the sub-encapsulation part and the isolating structure, and improving the encapsulation performance of the sub-encapsulation part.

According to a second aspect, an embodiment of this application provides a display panel, including: a substrate; a plurality of sub-pixels arranged on the substrate at intervals; an isolating structure disposed between at least some of adjacent sub-pixels; and a plurality of sub-encapsulation parts arranged on sides of corresponding sub-pixels away from the substrate, respectively.

A first recess and a second recess are formed and spaced apart in a direction away from the substrate on a side surface of the isolating structure proximate to a sub-pixel.

Each sub-encapsulation part is configured as a continuous film structure that covers the corresponding sub-pixel, the first recess, and the second recess.

According to the display panel provided in this embodiment of this application, the first recess and the second recess are formed on the isolating structure, and the sub-encapsulation part covers the corresponding sub-pixel, the first recess, and the second recess. In this way, on one hand, a coverage area of the sub-encapsulation part on the isolating structure is increased, so that a peeling path of the sub-encapsulation part is prolonged, and the encapsulation performance of the sub-encapsulation part is improved. On the other hand, because the sub-encapsulation part covers the second recess, even if the peeling occurs, the second recess may play a function of blocking, thereby increasing the difficulty of peeling occurring to the sub-encapsulation part, reducing a risk that the peeling occurs between the sub-encapsulation part and the isolating structure, and improving the encapsulation performance of the sub-encapsulation part.

According to a third aspect, an embodiment of this application provides a display panel, including: a substrate; a plurality of sub-pixels arranged on the substrate at intervals; an isolating structure arranged on the substrate and disposed between at least some of adjacent sub-pixels; and a plurality of sub-encapsulation parts arranged on sides of corresponding sub-pixels away from the substrate, respectively.

A first undercut part is arranged at a side of the isolating structure proximate to an adjacent sub-pixel, to isolate the two adjacent sub-pixels;

A second undercut part is further arranged at the side of the isolating structure and arranged apart from the first undercut part.

Each sub-encapsulation part corresponding to a sub-pixel adjacent to the isolating
structure also extends over a wall surface of the first undercut part and a wall surface of the second undercut part to form a continuous film structure.

According to the display panel provided in this embodiment of this application, the first undercut part and the second undercut part are arranged on the isolating structure, and the sub-encapsulation part covers the corresponding sub-pixel, the first undercut part, and the second undercut part. In this way, on one hand, a coverage area of the sub-encapsulation part on the isolating structure is increased, so that a peeling path of the sub-encapsulation part is prolonged, and the encapsulation performance of the sub-encapsulation part is improved. On the other hand, because the sub-encapsulation part covers over the second undercut part, even if the peeling occurs, the second undercut part may play a function of blocking, thereby increasing the difficulty of peeling occurring to the sub-encapsulation part, reducing a risk that the peeling occurs between the sub-encapsulation part and the isolating structure, and improving the encapsulation performance of the sub-encapsulation part.

According to a fourth aspect, an embodiment of this application provides a display device, including the display panel in any one of the foregoing embodiments.

### BRIEF DESCRIPTION OF THE DRAWINGS

FIG. 1 is a schematic sectional view showing a structure of a display panel in the related art.

FIG. 2A is a schematic sectional view showing partial structure of a display panel according to an embodiment of this application.

FIG. 2B is a schematic sectional view showing partial structure of another display panel according to an embodiment of this application.

FIG. 2C is a schematic sectional view showing partial structure of yet another display panel according to an embodiment of this application.

FIG. 2D is a schematic sectional view showing partial structure of yet another display panel according to an embodiment of this application.

FIG. 3 is a schematic sectional view showing a partial structure of an isolating structure of a display panel shown in FIG. 2A.

FIG. 4 is a schematic top view of an embodiment of part of the display panel shown in FIG. 2A.

FIG. 5A is a schematic top view of another embodiment of part of the display panel shown in FIG. 2A.

FIG. 5B is a schematic partial top view of yet another embodiment of part of the display panel shown in FIG. 2A.

FIG. 5C is a partial schematic view of FIG. 5B.

FIG. 6 is a schematic sectional view showing partial structure of a display panel according to another embodiment of this application.

FIG. 7 is a schematic sectional view showing partial structure of an isolating structure of the display panel shown in FIG. 6.

FIG. 8 and FIG. 9 are schematic structural views showing a manufacturing process of the display panel shown in FIG. 2A.

FIG. 10 is a schematic sectional view showing partial structure of a display panel according to another embodiment of this application.

FIG. 11 is a schematic sectional view showing partial structure of an isolating structure of the display panel shown in FIG. 10.

FIG. 12 is a schematic sectional view showing partial structure of a display panel according to another embodiment of this application.

FIG. 13 is a schematic sectional view showing partial structure of an isolating structure of the display panel shown in FIG. 12.

FIG. 14 is a schematic sectional view showing partial structure of a display panel according to another embodiment of this application.

FIG. 15 is a schematic sectional view showing partial structure of an isolating structure of the display panel shown in FIG. 14.

FIG. 16 is a schematic structural view showing a display device according to an embodiment of this application.

### DETAILED DESCRIPTION OF THE EMBODIMENTS

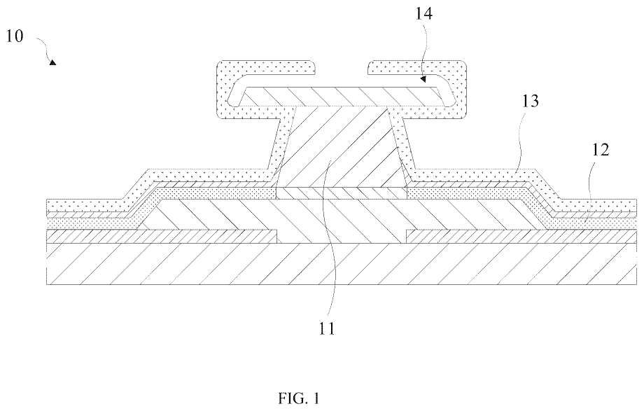

The organic light emitting diode (OLED) display technology is considered as a new type of flat panel display technology with most potential of a next generation. Compared with the liquid crystal display technology, the OLED display technology has advantages of low energy consumption, low cost, self-luminous, wide viewing angle, and fast response speed. Referring to FIG. 1, in the related OLED display technology, an inorganic encapsulation layer 13 of a display panel 10 covers a sub-pixel 12 and a side surface of an isolating structure 11, and a cavity region 14 is formed between the inorganic encapsulation layer 13 and a top surface of the isolating structure 11. However, after a force is exerted on the inorganic encapsulation layer 13, peeling easily occurs at a position proximate to the cavity region 14 due to the existing of the cavity region 14, so that the inorganic encapsulation layer 13 is peeled off the isolating structure 11. Therefore, the encapsulation performance of the inorganic encapsulation layer 13 is reduced, the reliability of display panel 10 is poor, and display effect is poor.

In view of at least one of the problems above, an embodiment of this application provides a display panel and a display device, which can improve the encapsulation performance of the sub-encapsulation part, thereby improving the reliability of the display panel and the display device.

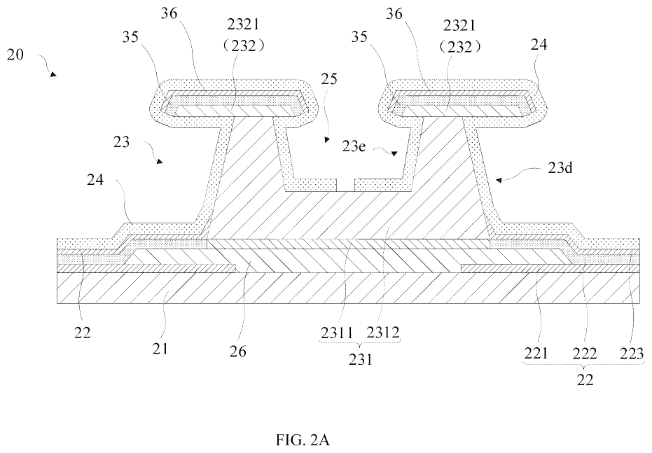

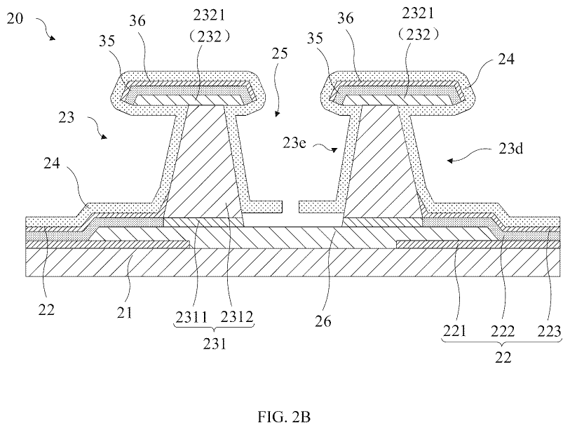

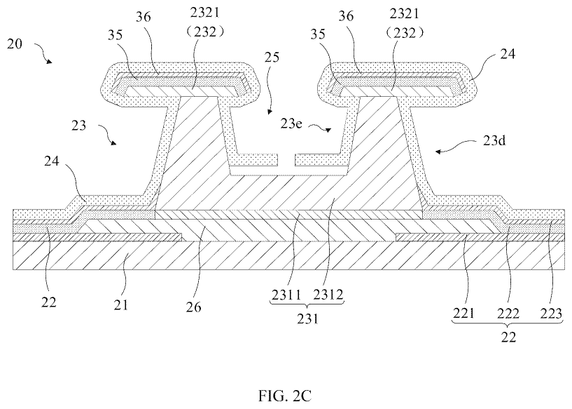

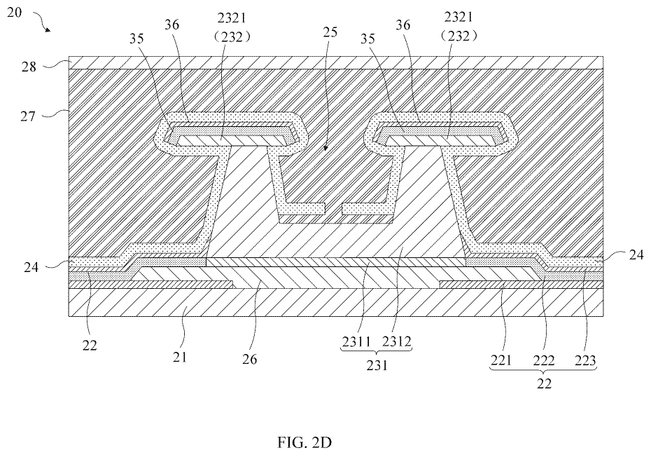

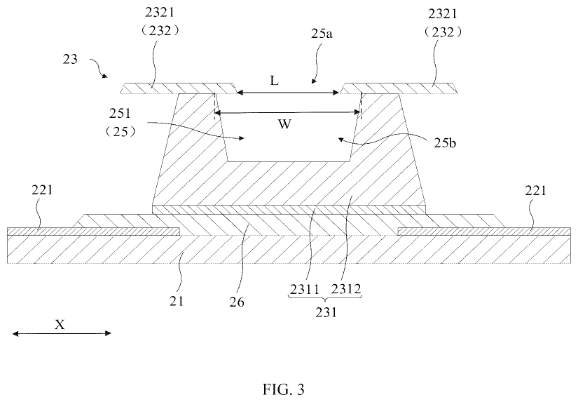

In a first aspect, referring to FIG. 2A, FIG. 2B, FIG. 2C, FIG. 2D, and FIG. 3, an embodiment of this application provides a display panel 20. The display panel 20 may be an organic light emitting diode (OLED) display panel 20, a quantum dot light emitting diode (QDLED) display panel 20.

The display panel 20 includes a substrate 21, a plurality of sub-pixels 22, an isolating structure 23, and a plurality of sub-encapsulation parts 24.

Specifically, the substrate 21 may be an array substrate. The multiple sub-pixels 22 are arranged on the substrate 21 at intervals. The isolating structure 23 is disposed between at least some of adjacent sub-pixels 22. The multiple sub-encapsulation parts 24 are arranged on sides of the corresponding sub-pixels 22 away from the substrate 21, respectively.

At least one groove 25 is formed on a top side of the isolating structure 23 away from the substrate 21, and the groove 25 has a groove cavity 25b proximate to the substrate 21 and an opening 25a away from the substrate 21. An orthographic projection of the opening 25a projected on the substrate 21 is within an orthographic projection of the groove cavity 25b projected on the substrate 21. That is, the groove 25 has a groove structure having a large cavity and a small opening.

Each of the plurality of sub-encapsulation parts 24 corresponding to the at least one sub-pixel 22 adjacent to the groove 25 further covers a side surface of the isolating structure 23 proximate to the sub-pixel 22, a top side of the isolating structure 23 away from the substrate 21, and at least part of a groove wall of the groove 25, that is, each of the plurality of sub-encapsulation parts 24 corresponding to the at least one sub-pixel 22 adjacent to the groove 25 extends along an outer contour of the isolating structure 23 from a side surface of the isolating structure 23 proximate to the sub-pixel 22, passes through the top side of the isolating structure 23 away from the substrate 21, and extends to the inner side of the groove 25.

In this way, in one aspect, compared with the related technology, in the embodiment of this application, a coverage area of the sub-encapsulation part 24 on the isolating structure 23 is increased, so that a peeling path from an end coverage location of the sub-encapsulation part 24 to the surface of the sub-pixel 22 is extended, thus improving the encapsulation performance of the sub-encapsulation part 24.

In another aspect, when the light-emitting material and the electrode material of the sub-pixel 22 are evaporated, the light-emitting material and the electrode material cannot cover the groove wall of the groove 25. However, because the sub-encapsulation part 24 extends to the groove wall of the groove 25, that is, the sub-encapsulation part 24 is in direct contact with the groove wall of the groove 25, thus the top of the isolating structure 23 is completely encapsulated. In a subsequent etching process, the light-emitting material and the electrode material at the top of the isolating structure 23 are retained, to form a light-emitting material layer 35 and an electrode material layer 36 which are stacked. Therefore, compared with the related technology, this embodiment of this application eliminates a cavity between the sub-encapsulation part 24 and the top of the isolating structure 23, thereby reducing a risk of peeling occurring between the sub-encapsulation part 24 and the isolating structure 23, and improving the encapsulation performance of the sub-encapsulation part 24.

In still another aspect, due to the extension of the sub-encapsulation part 24 to a groove wall of the groove 25, even if the peeling occurs, the groove wall of the groove 25 may play a function of blocking, so as to slow down peeling of the sub-encapsulation part 24 away the groove wall of the groove 25, thereby protecting the sub-encapsulation part 24, and reducing a risk of the peeling occurring between the sub-encapsulation part 24 and the isolating structure 23, and improving the encapsulation performance of the sub-encapsulation part 24.

In another aspect, the sub-encapsulation part 24 covers the side surface of the isolating structure 23 proximate to the sub-pixel 22, that is, the sub-encapsulation part 24 is in direct contact with the side surface of the isolating structure 23 proximate to the sub-pixel 22, which performs an encapsulation function and improves the encapsulation reliability of the sub-encapsulation part 24.

In one of the embodiments, the isolating structure 23 includes a partition body 231 and a blocking part 232 stacked on the substrate 21, and the blocking part 232 extends in a direction towards the sub-pixel 22 to protrude from the side surface of the partition body 231 proximate to the sub-pixel 22. The partition body 231 and the blocking part 232 define the groove 25.

It may be understood that, one end of the blocking part 232 proximate to the sub-pixel 22 protrudes from the side wall of the partition body 231, and a protruding part of the blocking part 232 may form a shielding, so that the isolating structure 23 has a function of isolating a light-emitting material and an electrode material.

It should be noted that the sub-encapsulation part 24 covers part of the side surface of the partition body 231 proximate to the sub-pixel 22, and covers a side surface of the blocking part 232 proximate to the substrate 21, namely a lower surface of the protruding part of the blocking part 232. In this way, a encapsulation structure is formed between the sub-encapsulation part 24 and the partition body 231, and another encapsulation structure is formed between the sub-encapsulation part 24 and the lower surface of the protruding part of the blocking part 232, which can effectively prevent external water vapor from diffusing towards the sub-pixel 22, and effectively preventing an external defect from extending towards the sub-pixel 22, thereby improving the encapsulation reliability of the sub-encapsulation part 24.

In an embodiment, two opposite ends of the blocking part 232 protrude from the side walls of the partition body 231, respectively. The sub-encapsulation parts 24 corresponding to the sub-pixels 22 arranged at two sides of the isolating structure 23 cover the lower surfaces of the protruding parts of the blocking parts 232 proximate to the sub-pixels 22 respectively, that is, each of the sub-encapsulation parts 24 corresponding to the sub-pixels 22 are in direct contact with the lower surfaces of the protruding parts of the blocking parts 232 proximate to the sub-pixels 22 respectively to form an encapsulation structure, thus effectively preventing external water vapor from diffusing towards the sub-pixels 22 along the surface of the isolating structure 23, and effectively preventing an external defect from extending towards the sub-pixels 22, thereby improving the encapsulation reliability of the sub-encapsulation parts 24.

In one of the embodiments, as shown in FIG. 3, the opening 25a penetrates through the blocking part 232 in a thickness direction of the substrate 21, a sub-groove 251 is formed on the top side of the partition body 231 away from the substrate 21, and the sub-groove 251 defines a groove cavity 25b.

In one of the embodiments, referring to FIG. 3, a dimension L of the opening 25a along the first direction X is less than a dimension W of the sub-groove 251 along the first direction X. The first direction X is perpendicular to a thickness direction of the substrate 21 and perpendicular to an extension direction of the groove 25. In this embodiment of this application, the groove 25 extends in a direction perpendicular to the sectional plane.

In one of the embodiments, as shown in FIG. 2B, the sub-groove 251 penetrates through the partition body 231 in the thickness direction of the substrate 21. In this way, an area that can be covered by the sub-encapsulation part 24 may be larger, thus improving the encapsulation reliability of the sub-encapsulation part 24.

In one of the embodiments, the sub-groove 251 is configured as a light transmitting hole. In this way, light may pass through the isolating structure 23, thereby improving the light transmittance of the display panel 20. In some embodiments, a down-screen function module (such as a down-screen camera) is arranged at the back of the display panel 20. By configuring the sub-groove 251 as the light transmitting hole, the working performance of the down-screen function module may be improved.

In one of the embodiments, referring to FIG. 2A, a light-emitting material layer 35 and an electrode material layer 36 are arranged in sequence and stacked on a top side of the blocking part 232 away from the substrate 21, and the sub-encapsulation part 24 corresponding to at least one sub-pixel 22 adjacent to the groove 25 further covers a top surface of the electrode material layer 36, side surfaces of the electrode material layer 36, and side surfaces of the light-emitting material layer 35.

In this way, the sub-encapsulation part 24 surrounds the light-emitting material layer 35 and the electrode material layer 36. Compared with the related technology, the embodiment of this application eliminates the cavity between the sub-encapsulation part 24 and the top side of the isolating structure 23, thereby reducing a risk of peeling that may occurs between the sub-encapsulation part 24 and the isolating structure 23, and improving the encapsulation performance of the sub-encapsulation part 24.

In one of the embodiments, referring to FIG. 2A and FIG. 3, the isolating structure 23 includes the partition body 231 and at least two sub-blocking parts 2321, which are arranged and stacked on the substrate 21. The at least two sub-blocking parts 2321 are arranged and spaced apart in the first direction X. That is, the at least two sub-blocking part 2321 are arranged in parallel between two adjacent sub-pixels 12. The partition body 231 and the two adjacent sub-blocking parts 2321 define the groove 25.

It may be understood that, when the isolating structure 23 includes only two sub-blocking parts 2321, the two sub-blocking part 2321 are arranged and spaced apart on two ends of the partition body 231 respectively along the first direction X. In addition, in the first direction X, both sub-blocking parts 2321 extend in directions away from the center of the partition body 231 to protrude from the side walls of the partition body 231 respectively. In this way, the isolating structure 23 may realize an effect of isolating the light-emitting materials of the two adjacent sub-pixels 22.

In one of the embodiments, as shown in FIG. 3, a sub-groove 251 is disposed on the top side of the partition body 231 away from the substrate 21, and orthographic projections of the two adjacent sub-blocking parts 2321 projected on the substrate 21 overlap an orthographic projection of the corresponding sub-groove 251 projected on the substrate 21. That is, the two adjacent sub-blocking parts 2321 are spaced apart from each other, and space between the two sub-blocking parts 2321 is the opening 25a of the groove 25. Further, the groove cavity 25b is in the sub-groove 251.

In this embodiment, the sub-groove 251 is a part of the groove 25, and the other part of the groove 25 consists of the space between the two sub-blocking parts 2321.

In an embodiment, the sub-encapsulation part 24 extends to and covers the groove wall of the sub-groove 251. On the one hand, there is no cavity between the sub-encapsulation part 24 and the isolating structure 23, thus reducing the risk of peeling occurring between the sub-encapsulation part 24 and the isolating structure 23. On the other hand, even if the peeling occurs, the opening 25a of the groove 25 may play a function of blocking, to slow down outward peeling of the sub-encapsulation part 24 away the groove wall of the sub-groove 251, thereby protecting the sub-encapsulation part 24, and reducing the risk that the peeling occurs between the sub-encapsulation part 24 and the isolating structure 23, and improving the encapsulation performance of the sub-encapsulation part 24.

In one of the embodiments, the minimum distance L between two adjacent sub-blocking parts 2321 is less than a dimension W in the first direction X of one end of the sub-groove 251 away from the substrate 21.

In this way, the groove 25 has a groove structure having a small cavity and a large opening. In addition, when the light-emitting material and the electrode material of the sub-pixel 22 are evaporated, the light-emitting material and the electrode material cannot cover a side surface of the sub-blocking part 2321 proximate to the sub-groove 251. However, because the sub-encapsulation part 24 extends to the groove wall of the sub-groove 251, that is, the sub-encapsulation part 24 is in direct contact with the side surface of the sub-blocking part 2321 proximate to the sub-groove 251, the top of the isolating structure 23 is completely encapsulated. In a subsequent etching process, the light-emitting material and the electrode material at the top of the isolating structure 23 are retained, to form a light-emitting material layer 35 and an electrode material layer 36 which are stacked. Therefore, compared with the related technology, this embodiment of this application eliminates a cavity between the sub-encapsulation part 24 and the top of the isolating structure 23, thereby reducing a risk of peeling occurring between the sub-encapsulation part 24 and the isolating structure 23, and improving the encapsulation performance of the sub-encapsulation part 24.

In one of the embodiments, at least one groove 25 is formed on the isolating structure 23 between the two adjacent sub-pixels 22.

In one of the embodiments, referring to FIG. 2A, one groove 25 is formed on the isolating structure 23 between the two adjacent sub-pixels 22. The sub-encapsulation parts 24 corresponding to the two adjacent sub-pixels 22 extend to cover two groove walls of the same groove 25, respectively. In this way, the groove 25 may achieve an enhanced encapsulation for the sub-encapsulation parts 24 on the two groove walls of the groove 25, thereby improving the encapsulation reliability of the display panel 20.

In one of the embodiments, the sub-encapsulation part 24 corresponding to the sub-pixel 22 adjacent to the groove 25 further covers a side, proximate to the groove 25, of the blocking part 232 adjacent to the sub-pixel 22.

In a specific example, referring to FIG. 2A, the sub-encapsulation part 24 corresponding to the sub-pixel 22 adjacent to the groove 25 further covers a side, proximate to the groove 25, of the sub-blocking part 2321 adjacent to the sub-pixel 22.

It may be understood that, when the light-emitting material and the electrode material of the sub-pixel 22 are evaporated, the light-emitting material and the electrode material cannot cover the side surface of the sub-blocking part 2321 proximate to the sub-groove 251. However, because the sub-encapsulation part 24 extends to the groove wall of the sub-groove 251, that is, the sub-encapsulation part 24 is in direct contact with the side surface of the sub-blocking part 2321 proximate to the sub-groove 251, thus the top of the isolating structure 23 is completely encapsulated. In a subsequent etching process, the light-emitting material and the electrode material at the top of the isolating structure 23 are retained, to form a light-emitting material layer 35 and an electrode material layer 36 which are stacked. Therefore, compared with the related technology, this embodiment of this application eliminates the cavity between the sub-encapsulation part 24 and the top of the isolating structure 23, thereby reducing a risk of peeling occurring between the sub-encapsulation part 24 and the isolating structure 23, and improving the encapsulation performance of the sub-encapsulation part 24.

In one of the embodiments, the sub-encapsulation part 24 corresponding to the sub-pixel 22 adjacent to the groove 25 further covers one groove wall, adjacent to the sub-pixel 22, of the sub-groove 251. That is, the sub-encapsulation part 24 covers the groove wall of the sub-groove 251 adjacent to the sub-pixel 22.

In one of the embodiments, the sub-encapsulation part 24 corresponding to the sub-pixel 22 adjacent to the groove 25 further covers at least part of the groove walls of the sub-groove 251.

In an embodiment, the sub-encapsulation part 24 corresponding to the sub-pixel 22 adjacent to the groove 25 further covers the groove wall and part of a bottom wall of the sub-groove 251 adjacent to the sub-pixel 22.

In this way, for one sub-pixel 22, the sub-encapsulation part 24 may form two encapsulation rings, thereby improving the encapsulation performance of the sub-encapsulation part 24. The sub-encapsulation part 24, which covers the side of the sub-blocking part 2321 proximate to the sub-groove 251, one groove wall of the sub-groove 251, and part of the bottom wall of the sub-groove 251, forms one encapsulation ring. The sub-encapsulation part 24, which covers on the side surface of the isolating structure 23 proximate to the sub-pixel 22, forms another encapsulation ring.

In one of the embodiments, referring to FIG. 2C, part of the sub-encapsulation part 24 is located at a side of the bottom wall of the sub-groove 251 away from the substrate 21, and there is a gap between the part of the sub-encapsulation part 24 and the bottom wall of the sub-groove 251. The gap is formed in the following way. In a manufacturing process, the gap is provided with the light-emitting material layer 35 and the electrode material layer 36, and the part of the sub-encapsulation part 24 covers the light-emitting material layer 35 and the electrode material layer 36, and in a subsequent wet etching process, the light-emitting material layer 35 and the electrode material layer 36 in the gap are removed, so that the gap is formed between the part of the sub-encapsulation part 24 and the bottom wall of the sub-groove 251.

In one of the embodiments, the sub-encapsulation part 24 is an inorganic film layer.

In one of the embodiments, referring to FIG. 2D, the display panel 20 further includes a first encapsulation layer 27 and a second encapsulation layer 28. The first encapsulation layer 27 covers at least one side, away from the substrate 21, of each of the plurality of sub-encapsulation parts 24. The second encapsulation layer 28 covers one side of the first encapsulation layer 27 away from the substrate 21. The first encapsulation layer 27 is an organic film layer, and the second encapsulation layer 28 is an inorganic film layer, such that the encapsulation performance of the display panel 20 may be improved. It may be understood that the first encapsulation layer 27 may also fill the gap between the sub-encapsulation part 24 and the bottom wall of the sub-groove 251.

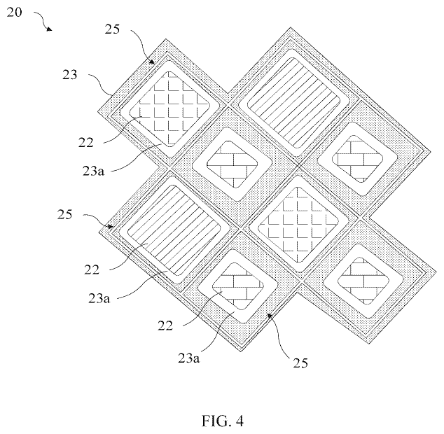

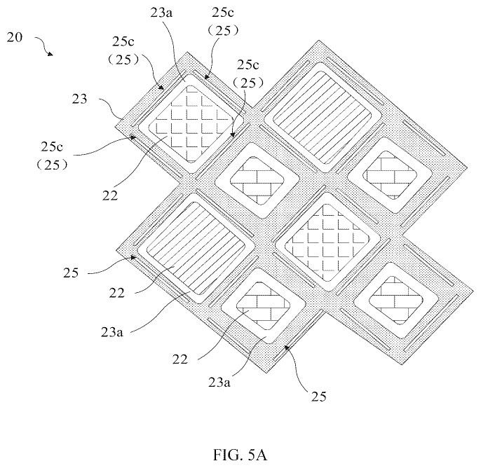

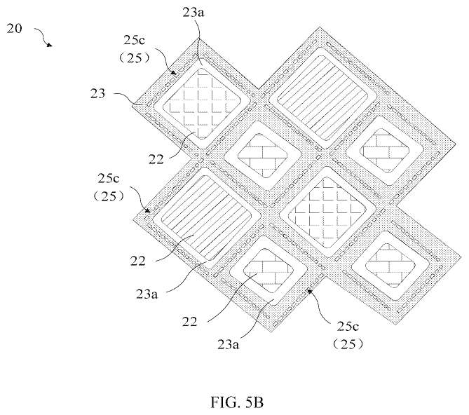

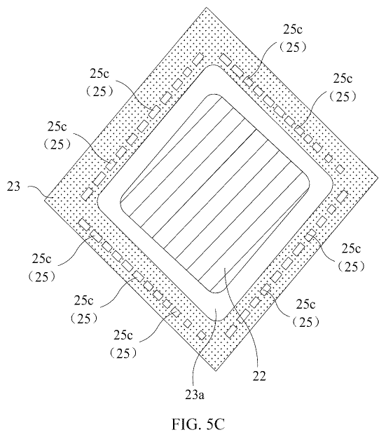

In one of the embodiments, referring to FIG. 4, FIG. 5A, and FIG. 5B, the isolating structure 23 defines multiple isolation openings 23a, and a sub-pixel 22 is correspondingly arranged in each isolation opening 23a. The groove 25 is arranged to surround at least part of the periphery of the isolation opening 23a, that is, the groove 25 is arranged to surround at least part of the periphery of the sub-pixel 22.

In an example, the isolating structure 23 has a weblike structure, that is, an orthographic projection of the isolating structure 23 projected on the substrate 21 is weblike. It may be understood that the weblike isolating structure 23 has meshes, and each mesh is one isolation opening 23a.

In one of the embodiments, the groove 25 is arranged to surround at least part of the periphery of the isolation opening 23a.

In one of the embodiments, referring to FIG. 5A and FIG. 5B, the groove 25 is a discontinuous groove, that is, each groove 25 includes multiple groove sections 25c, and the multiple groove sections 25c are arranged to surround the periphery of the isolation opening 23a.

In one of the embodiments, referring to FIG. 5A, four groove sections 25c are arranged on the periphery of one isolation opening 23a, that is, the isolation opening 23a has four sides, and one groove section 25c is disposed at each side.

In another embodiment, referring to FIG. 5B and FIG. 5C, more groove sections 25c are arranged on the periphery of the isolation opening 23a. Specifically, the isolation opening 23a has four sides, and multiple groove sections 25c are disposed at each side. In this way, the groove sections 25c are island-like and distributed on the periphery of the isolation opening 23a.

It should be noted that the differences between the grooves 25 shown in FIG. 5A and FIG. 5B are that a length of the groove section 25c in FIG. 5A is greater than a length of the groove section 25c in FIG. 5B, and the number of the groove sections 25c in FIG. 5A is less than the number of the groove sections 25c in FIG. 5B.

It may be understood that lengths of the groove sections 25c may be equal or not. The spacing between any two adjacent groove sections 25c may be the same or not. A specific arrangement of the groove sections 25c is not limited in the embodiments of this application.

In an embodiment, multiple groove section 25c are arranged at uniform intervals to surround the periphery of the isolation opening 23a, that is, distances between any two adjacent groove sections 25c are equal, such that not only the encapsulation reliability around the sub-pixel 22 may be improved, but also the encapsulation around the sub-pixel 22 may be more uniform.

It may be understood that when groove 25 is a discontinuous groove, the blocking part 232 is an integrated structure.

It should be noted that when groove 25 is a discontinuous groove, as shown in FIG. 2B, the groove 25 may penetrate through the isolating structure 23 in the thickness direction of the substrate 21. In this case, the isolating structure 23 is not divided into multiple independent structures by the groove 25, that is, the isolating structure 23 is still an integrated structure.

In one of the embodiments, referring to FIG. 4, the groove 25 is arranged to surround the whole periphery of the isolation opening 23a, that is, the groove 25 is a continuous groove 25. In this way, at least two encapsulation rings may be formed in the periphery of the sub-pixel 22, thereby further improving the encapsulation performance of the sub-encapsulation part 24.

It may be understood that, with reference to FIG. 2A and FIG. 4, when the groove 25 is a continuous groove 25, and when one groove 25 is arranged on the periphery of one sub-pixel 22, the isolating structure 23 includes two sub-blocking parts 2321, and the two sub-blocking part 2321 are arranged and spaced apart on the partition body 231, and the groove 25 is disposed between the two sub-blocking parts 2321.

In one of the embodiments, the orthographic projection of the groove 25 surrounding each isolation opening 23a, which is projected on the substrate 21, has a closed shape. That is, the groove 25 forms a closed shape. For example, the groove 25 may have a circular shape, a rectangular shape, a triangular shape, or the like.

In one of the embodiments, the orthographic projection of all grooves 25 formed on the isolating structure 23, which is projected on the substrate 21, has a weblike structure. In this case, all the grooves 25 are connected to form the weblike groove 25. In this way, the grooves 25 are arranged relatively regularly, and a distribution density is relatively large, thereby further improving the encapsulation performance of the sub-encapsulation part 24.

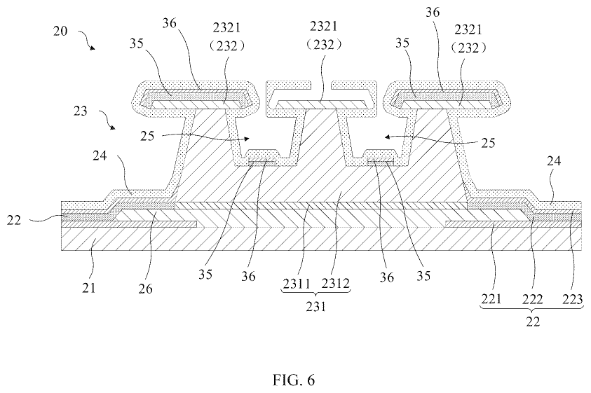

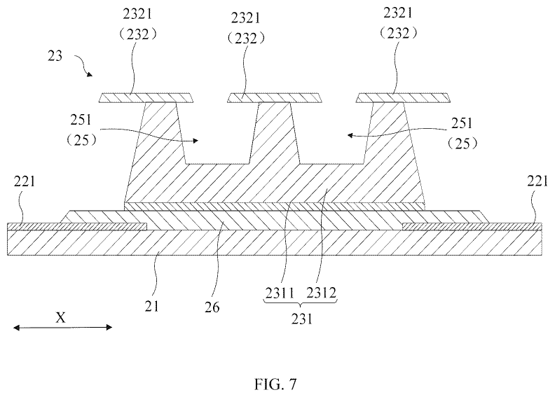

In one of the embodiments, referring to FIG. 6 and FIG. 7, two parallel grooves 25 are formed between two adjacent sub-pixels 22. The sub-encapsulation parts 24 corresponding to the two adjacent sub-pixels 22 extend and cover the grooves 25 adjacent to the corresponding sub-pixels 22 respectively.

In this way, the two adjacent sub-encapsulation parts 24 may cover their respective grooves 25, thereby increasing the coverage area of each sub-encapsulation part 24 in the groove 25, and further improving the encapsulation performance of the sub-encapsulation part 24.

In a specific embodiment, referring to FIG. 6 and FIG. 7, the isolating structure 23 includes three sub-blocking parts 2321 arranged at intervals along the first direction X. The partition body 231 and three sub-blocking parts 2321 jointly define two grooves 25. The two groove 25 are arranged and spaced apart along the first direction X. The sub-encapsulation parts 24 corresponding to the two adjacent sub-pixels 22 extend and cover their respective adjacent grooves 25.

In one of the embodiments, the sub-encapsulation part 24 corresponding to the sub-pixel 22 adjacent to the groove 25 further covers the side of the blocking part 232 proximate to the groove 25.

In a specific embodiment, the sub-encapsulation part 24 corresponding to the sub-pixel 22 adjacent to the groove 25 further covers a side, proximate to the groove 25, of the sub-blocking part 2321 adjacent to the sub-pixel 22.

It may be understood that, when the light-emitting material and the electrode material of the sub-pixel 22 are evaporated, the light-emitting material and the electrode material cannot cover the side surface of the sub-blocking part 2321 proximate to the sub-groove 251. However, because the sub-encapsulation part 24 extends to the groove wall of the sub-groove 251, that is, the sub-encapsulation part 24 is in direct contact with the side surface of the sub-blocking part 2321 proximate to the sub-groove 251, the top of the isolating structure 23 is completely encapsulated. In a subsequent etching process, the light-emitting material and the electrode material at the top of the isolating structure 23 are retained, to form the light-emitting material layer 35 and the electrode material layer 36 which are stacked. Therefore, compared with the related technology, this embodiment of this application eliminates the cavity between the sub-encapsulation part 24 and the top of the isolating structure 23, thereby reducing a risk of peeling occurring between the sub-encapsulation part 24 and the isolating structure 23, and improving the encapsulation performance of the sub-encapsulation part 24.

In one of the embodiments, the sub-encapsulation part 24 corresponding to the sub-pixel 22 adjacent to the groove 25 further covers one groove wall of the sub-groove 251 adjacent to the sub-pixel 22. That is, the sub-encapsulation part 24 further covers a side wall of the sub-groove 251 adjacent to the sub-pixel 22.

In this way, the encapsulation performance of the sub-encapsulation part 24 may be further improved.

In one of the embodiments, the sub-encapsulation part 24 corresponding to the sub-pixel 22 adjacent to the groove 25 further covers all groove walls of the sub-groove 251 adjacent to the sub-pixel 22. It may be understood that the side of the sub-blocking part 2321 proximate to the sub-groove 251 is also a part of a groove wall.

In this way, for a sub-pixel 22, the sub-encapsulation part 24 may form three encapsulation rings, thereby improving the encapsulation performance of the sub-encapsulation part 24. One encapsulation ring is formed on each of the groove walls at two sides, in the first direction X, of the sub-groove 251, and a side surface of the isolating structure 23 proximate to the sub-pixel 22 forms a third encapsulation ring.

It should be noted that the light-emitting material layer 35 and the electrode material layer 36 may be formed on the bottom wall of the sub-groove 251. When the light-emitting material layer 35 and the electrode material layer 36 are formed on the bottom wall of the sub-groove 251, the sub-encapsulation part 24 may cover the light-emitting material layer 35 and the electrode material layer 36.

In one of the embodiments, referring to FIG. 6, the sub-encapsulation part 24 covers all the groove walls of the groove 25, which is adjacent to the corresponding sub-pixel 22, and extends from inside of the groove 25 to the top side, away from the substrate 21, of the sub-blocking part 2321 located in the middle, and a cavity is formed between the sub-encapsulation part 24 and the top side of the sub-blocking part 2321. In such an embodiment, even if the cavity is formed between the sub-blocking part 2321 in the middle and the end portion of the sub-encapsulation part 24, because the sub-encapsulation part 24 forms three encapsulation rings, this embodiment of this application, compared with a related technology, may also improve the encapsulation performance of the sub-encapsulation parts 24 when the peeling of the sub-encapsulation part 24 occurs.

In one of the embodiments, the sub-pixel 22 includes a first electrode 221, a light-emitting functional part 222, and a second electrode 223, which are arranged and stacked in a direction away from the substrate 21. The second electrode 223 of the sub-pixel 22 is electrically connected to the isolating structure 23.

In this way, it is easy to connect the second electrode 223 of the sub-pixel 22 to a pixel driving circuit by means of the isolating structure 23, so that an arrangement of the wiring of the display area is optimized.

It should be noted that the first electrode 221 may be an anode, and the second electrode 223 may be a cathode. Both the first electrode 221 and the second electrode 223 are electrically connected to the pixel driving circuit. If the first electrode 221 is a cathode, the isolating structure 23 transmits a VSS signal. If the first electrode 221 is an anode, the isolating structure 23 transmits a VDD signal.

It may be understood that the light-emitting functional part 222 includes at least an emission layer (EML). In addition, the light-emitting functional part 222 may further include one or more of a hole injection layer (HIL), a hole transport layer (HTL), an electron injection layer (EIL), an electron transport layer (ETL), a hole block layer (HBL), and an electron block layer (EBL). Alternatively, the light-emitting functional part 222 may be a laminated light emitting layer, namely, may include at least two light emitting layers and a charge generation layer (CGL) located between adjacent light emitting layers.

In one of the embodiments, the partition body 231 includes at least one metal layer, and the second electrode 223 of the sub-pixel 22 is electrically connected to the partition body 231. In an embodiment, the partition body 231 includes a metal layer. Further, the material of the partition body 231 includes at least one of a metal or a metal oxide. For example, the metal may be silver, copper, titanium, aluminum, or the like, and the metal oxide may be tin oxide, zinc oxide, cadmium oxide, indium oxide, indium tin oxide, zinc oxide indium, zinc oxide crop, zinc aluminum oxide, titanium tantalum oxide, or the like.

In one of the embodiments, the partition body 231 includes a first metal layer 2311 and a second metal layer 2312, which are arranged and stacked in a direction away from the substrate 21. The resistivity of the second metal layer 2312 is less than that of the first metal layer 2311. The second electrode 223 of the sub-pixel 22 is in direct contact with the second metal layer 2312.

In this way, on the one hand, the electrical contact resistance between the isolating structure 23 and the second electrode 223 is reduced, and on the other hand, the resistance of the isolating structure 23 is reduced, thereby reducing the power consumption of the display panel 20.

In an example, a material of the first metal layer 2311 may be Mo, and a material of the second metal layer 2312 may be A1. A material of the sub-blocking part 2321 may be Ti.

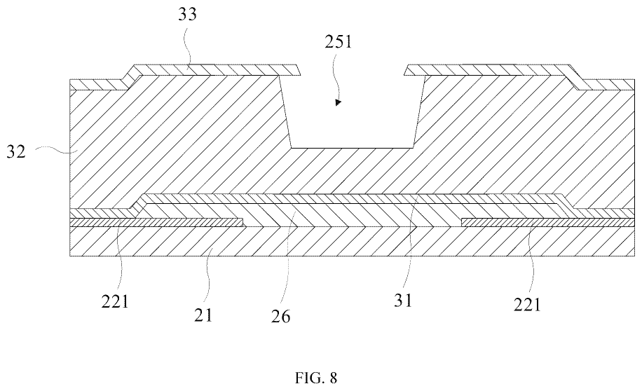

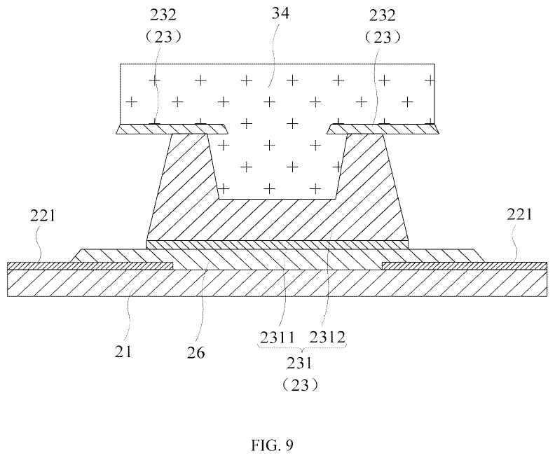

In one of the embodiments, referring to FIG. 8 and FIG. 9, an embodiment of this application provides a preparation method of a display panel 20 shown in FIG. 2A.

The preparation method of the display panel 20 includes steps S100 to S900.

In step S100, a first electrode 221 and a pixel defining layer 26 are formed on the substrate 21 sequentially.

In step S200, a first metal material layer 31, a second metal material layer 32, and a third metal material layer 33 are arranged and stacked on the substrate 21 sequentially.

In step S300, the third metal material layer 33 is etched to form an opening 25a of a groove 25.

In step S400, the second metal material layer 32 is etched to form the groove 25.

In step S500, a photoresist 34 is formed on the third metal material layer 33, and part of a surface of the third metal material layer 33 is exposed.

In step S600, the third metal material layer 33, the second metal material layer 32, and the first metal material layer 31 are etched to form an isolating structure 23.

In step S700, a sub-pixel 22 of a first color and a corresponding sub-encapsulation part 24 are formed on the substrate 21.

In step S800, a sub-pixel 22 of a second color and a corresponding sub-encapsulation part 24 are formed on the substrate 21.

In one of the embodiments, after the step S800, the preparation method of the display panel 20 further includes step S900.

In step S900, a sub-pixel 22 of a third color and a corresponding sub-encapsulation part 24 are formed on the substrate 21.

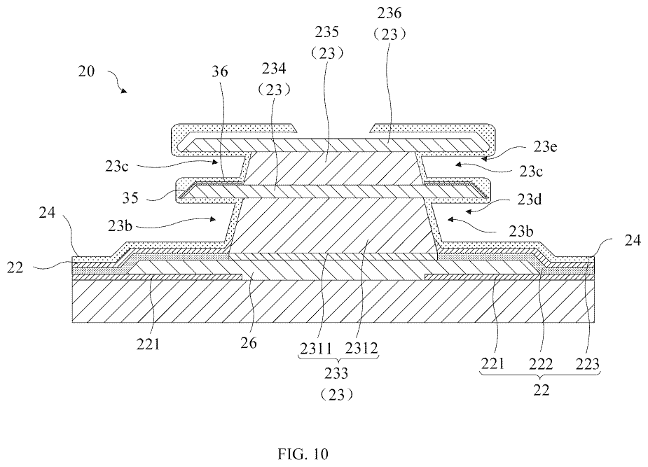

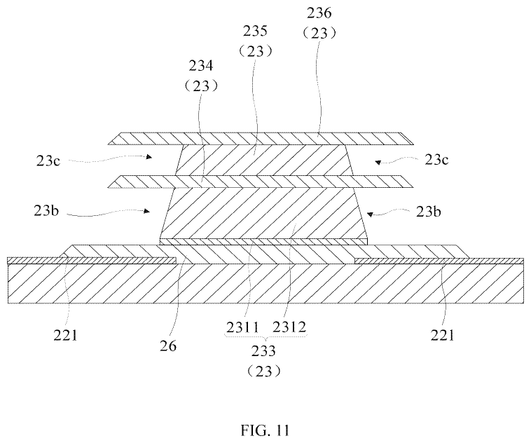

In a second aspect, as shown in FIG. 10 and FIG. 11, an embodiment of this application provides a display panel 20. The display panel 20 may be an organic light emitting diode (OLED) display panel 20, or a quantum dot light emitting diode (QDLED) display panel 20.

The display panel 20 includes a substrate 21, a plurality of sub-pixels 22, an isolating structure 23, and a plurality of sub-encapsulation parts 24.

Specifically, the substrate 21 may be an array substrate. The multiple sub-pixels 22 are arranged on the substrate 21 at intervals. The isolating structure 23 is disposed between at least some of adjacent sub-pixels 22. The multiple sub-encapsulation parts 24 are arranged on sides of the corresponding sub-pixels 22 away from the substrate 21, respectively.

A first recess 23b and a second recess 23c are formed and spaced apart in a direction away from the substrate 21 on a side surface of the isolating structure 23 proximate to the sub-pixel 22. The sub-encapsulation part 24 is configured as a continuous film structure that covers the corresponding sub-pixel 22, the first recess 23b, and the second recess 23c.

It should be noted that, in the embodiment of this application, a pixel defining layer 26 is arranged on the substrate 21, and the isolating structure 23 is arranged on a side of the pixel defining layer 26 away from the substrate 21. The isolating structure 23 defines multiple isolation openings 23a, and the multiple sub-pixels 22 are arranged in the multiple isolation openings 23a, respectively.

In this application, the first recess 23b and the second recess 23c may also be understood as grooves that face the isolation opening 23a.

According to the display panel 20 provided in this embodiment of this application, the first recess 23b and the second recess 23c are formed on the isolating structure 23, and the sub-encapsulation part 24 covers the corresponding sub-pixel 22, the first recess 23b, and the second recess 23c. In this way, on one hand, a coverage area of the sub-encapsulation part 24 on the isolating structure 23 is increased, so that a peeling path of the sub-encapsulation part 24 is prolonged, and the encapsulation performance of the sub-encapsulation part 24 is improved. On the other hand, because the sub-encapsulation part 24 covers the second recess 23c, even if the peeling occurs, the second recess 23c may play a function of blocking, thereby increasing the difficulty of peeling occurring to the sub-encapsulation part 24, reducing a risk that the peeling occurs between the sub-encapsulation part 24 and the isolating structure 23, and improving the encapsulation performance of the sub-encapsulation part 24.

In one of the embodiments, as shown in FIG. 11, the isolating structure 23 includes a first partition body 233, a first blocking part 234, a second partition body 235, and a second blocking part 236, which are arranged and stacked in a direction away from the substrate 21. The first blocking part 234 extends in a direction towards the isolation opening 23a to protrude from the side surface of the first blocking part 234. The second blocking part 236 extends in a direction towards the isolation opening 23a to protrude from the side surface of the second partition body 235. The first blocking part 234, the first partition body 233, and the substrate 21 define the first recess 23b. The second blocking part 236, the second partition body 235, and the first blocking part 234 define the second recess 23c.

That is, the substrate 21, the first partition body 233, and the first blocking part 234 define a groove facing the isolation opening 23a. The first blocking part 234, the second partition body 235, and the second blocking part 236 define another groove facing the isolation opening 23a. In a specific embodiment, the pixel defining layer 26, the first partition body 233, and the first blocking part 234 define a groove facing the isolation opening 23a.

In the configuration above, the first recess 23b and the second recess 23c are formed on the isolating structure 23 easily, thereby reducing difficulty in arranging the first recess 23b and the second recess 23c.

In an embodiment, referring to FIG. 10, the light-emitting material layer 35 and the electrode material layer 36 are arranged and stacked in sequence on the top side of the first blocking part 234 away from the substrate 21, and the sub-encapsulation part 24 further covers a top surface of the electrode material layer 36, a side surface of the electrode material layer 36, and a side surface of the light-emitting material layer 35.

In an embodiment, after extending over and covers the surfaces of the first recess 23b and the second recess 23c, the sub-encapsulation part 24 also extends to the top side of the second blocking part 236 away from the substrate 21, and a cavity is formed between the sub-encapsulation part 24 and the top surface of the second blocking part 236.

In this way, on one hand, a coverage area of the sub-encapsulation part 24 on the isolating structure 23 is increased, so that a peeling path of the sub-encapsulation part 24 is prolonged, and the encapsulation performance of the sub-encapsulation part 24 is improved. On the other hand, because the sub-encapsulation part 24 covers the second recess 23c, even if the sub-encapsulation part 24 peels from the top surface of the second blocking part 236, the second recess 23c may play a function of blocking, thereby increasing the difficulty of the peeling occurring to the sub-encapsulation part 24, reducing a risk that the peeling occurs between the sub-encapsulation part 24 and the isolating structure 23, and improving the encapsulation performance of the sub-encapsulation part 24.

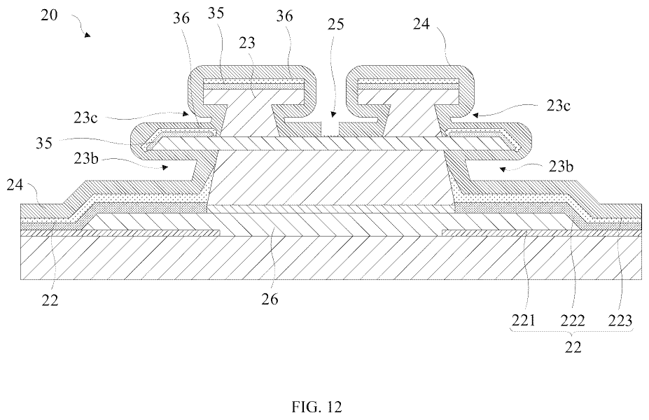

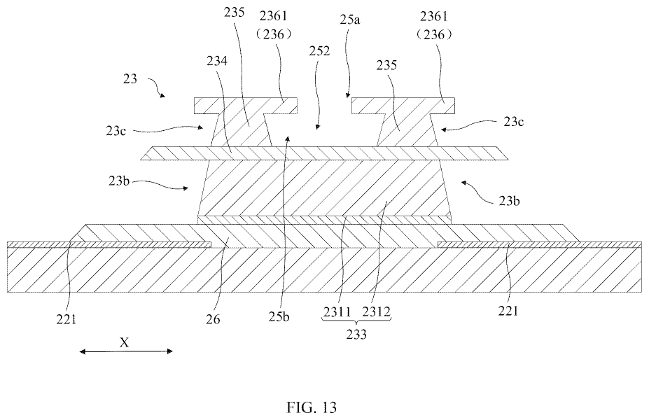

In one of the embodiments, as shown in FIGS. 12 and 13, at least one groove 25 is formed on the top side of the isolating structure 23 away from the substrate 21, and the groove 25 has a groove cavity 25b proximate to the substrate 21 and an opening 25a away from the substrate 21. The orthographic projection of the opening 25a projected on the substrate 21 is within the orthographic projection of the groove cavity 25b projected on the substrate 21, that is, the groove 25 has a groove structure having a large cavity and a small opening.

The sub-encapsulation part 24 corresponding to the at least one sub-pixel 22 adjacent to the groove 25 further covers a side surface of the isolating structure 23 proximate to the sub-pixel 22, the top side of the isolating structure 23 away from the substrate 21, and at least part of the groove wall of the groove 25, that is, the sub-encapsulation part 24 corresponding to the at least one sub-pixel 22 adjacent to the groove 25 extends along an outer contour of the isolating structure 23 from the side surface of the isolating structure 23 proximate to the sub-pixel 22, passes through the top side of the isolating structure 23 away from the substrate 21, and extends to the inner side of the groove 25.

In this way, in one aspect, in the embodiment of this application, a coverage area of the sub-encapsulation part 24 on the isolating structure 23 is increased, so that a peeling path from an end coverage location of the sub-encapsulation part 24 to the surface of the sub-pixel 22 is extended, thus improving the encapsulation performance of the sub-encapsulation part 24.

In another aspect, when the light-emitting material and the electrode material of the sub-pixel 22 are evaporated, the light-emitting material and the electrode material cannot cover the groove wall of the groove 25. However, because the sub-encapsulation part 24 extends to the groove wall of the groove 25, that is, the sub-encapsulation part 24 is in direct contact with the groove wall of the groove 25, thus the top of the isolating structure 23 is completely encapsulated. In a subsequent etching process, the light-emitting material and the electrode material at the top of the isolating structure 23 are retained. Therefore, compared with the related technology, this embodiment of this application eliminates the cavity between the sub-encapsulation part 24 and the top of the isolating structure 23, thereby reducing a risk of peeling occurring between the sub-encapsulation part 24 and the isolating structure 23, and improving the encapsulation performance of the sub-encapsulation part 24.

In still another aspect, because the sub-encapsulation part 24 extends to a groove wall of the groove 25, even if the peeling occurs, the groove wall of the groove 25 may play a function of blocking, so as to slow down the peeling of the sub-encapsulation part 24 away the groove wall of the groove 25, thereby protecting the sub-encapsulation part 24, and reducing a risk that the peeling occurs between the sub-encapsulation part 24 and the isolating structure 23, and improving the encapsulation performance of the sub-encapsulation part 24.

In another aspect, the sub-encapsulation part 24 covers the side surface of the isolating structure 23 proximate to the sub-pixel 22, that is, the sub-encapsulation part 24 is in direct contact with the side surface of the isolating structure 23 proximate to the sub-pixel 22, which performs an encapsulation function and improves the encapsulation reliability of the sub-encapsulation part 24.

It should be noted that a structure of the groove 25 in the embodiments of the second aspect may be the same as a structure of the groove 25 in the embodiments of the first aspect, and the structure of the groove 25 will not be described in detail hereinafter in the embodiments of this application repeatedly.

In one of the embodiments, the light-emitting material layer 35 and the electrode material layer 36 are arranged and stacked in sequence on the top side of the second blocking part 236 away from the substrate 21, and the sub-encapsulation part 24 further covers a top surface of the electrode material layer 36, a side surface of the electrode material layer 36, and a side surface of the light-emitting material layer 35.

In this way, a cavity between the sub-encapsulation part 24 and the top of the isolating structure 23 is eliminated, thereby reducing a risk of peeling occurring between the sub-encapsulation part 24 and the isolating structure 23, and further improving the encapsulation performance of the sub-encapsulation part 24.

In one of the embodiments, referring to FIG. 12 and FIG. 13, the groove 25 penetrates through the second blocking part 236 and at least part of the second partition body 235 in a thickness direction of the substrate 21. In this way, the groove 25 can have enough space beneficial for attachment of the sub-encapsulation part 24.

In one of the embodiments, the groove 25 penetrates through the whole second partition body 235 in a thickness direction of the substrate 21. In this way, a depth of the groove 25 may be relatively deep, and space for attaching the sub-encapsulation part 24 is relatively large, thereby improving the encapsulation reliability of the sub-encapsulation part 24.

In one of the embodiments, the groove 25 is configured as a light transmitting hole. In this way, light may pass through the isolating structure 23, which improves the light transmittance of the display panel 20. In some embodiments, a down-screen function module (for example, a down-screen camera) is arranged on the back of the display panel 20. By configuring the groove 25 as a light transmitting hole, the working performance of the down-screen function module may be improved.

In one of the embodiments, as shown in FIG. 13, the opening 25a penetrates through the second blocking part 236 in a thickness direction of the substrate 21. The groove 25 includes a first sub-groove 252, and the first sub-groove 252 penetrates through the second partition body 235 in the thickness direction of the substrate 21. That is, a bottom wall of the first sub-groove 252 is disposed on a surface of the first blocking part 234. In this way, a coverage area of the sub-encapsulation part 24 in the first sub-groove 252 is improved.

In one of the embodiments, the first blocking part 234, the second partition body 235, and the second blocking part 236 define the groove 25, and the first sub-groove 252 defines the groove cavity 25b.

In a specific embodiment, the second blocking part 236 includes two second sub-blocking parts 2361 arranged and spaced apart along the first direction X. The first blocking part 234, the second partition body 235 and two second sub-blocking parts 2361 define the groove 25.

In one of the embodiments, a first sub-groove 252 is disposed on the top side of the second partition body 235 away from the substrate 21, and an orthographic projection of two second sub-blocking parts 2361 projected on the substrate 21 overlaps an orthographic projection of the first sub-groove 252 projected on the substrate 21, to define the opening 25a of the groove 25. The groove cavity 25b is located inside the first sub-groove 252.

It should be noted that the first sub-groove 252 is one part of the groove 25, and the other part of the groove 25 includes space between the two second sub-blocking parts 2361.

In one of the embodiments, a dimension of the opening 25a along the first direction X is less than a dimension of the first sub-groove 252 along the first direction X, and the first direction X is perpendicular to the thickness direction of the substrate 21 and perpendicular to an extension direction of the groove 25.

In a specific embodiment, the minimum distance between two adjacent second sub-blocking parts 2361 is less than a dimension, along the first direction X, of an end of the first sub-groove 252 away from the substrate 21.

In this way, the groove 25, having a small cavity and a large opening, is formed. In addition, when the light-emitting material and the electrode material of the sub-pixel 22 are evaporated, the light-emitting material and the electrode material do not cover a side surface of the second sub-blocking part 2361 proximate to the first sub-groove 252. However, the sub-encapsulation part 24 extends to a groove wall of the first sub-groove 252, that is, the sub-encapsulation part 24 is in direct contact with a side surface of the second sub-blocking part 2361 proximate to the first sub-groove 252, therefore the top of the isolating structure 23 is completely encapsulated. In a subsequent etching process, the light-emitting material and the electrode material at the top of the isolating structure 23 are retained. Therefore, compared with the related technology, this embodiment of this application eliminates the cavity between the sub-encapsulation part 24 and the top of the isolating structure 23, thereby reducing a risk of peeling occurring between the sub-encapsulation part 24 and the isolating structure 23, and improving the encapsulation performance of the sub-encapsulation part 24.

In one of the embodiments, the sub-encapsulation part 24 corresponding to the at least one sub-pixel 22 adjacent to the groove 25 further covers a side, proximate to the groove 25, of the second blocking part 236 adjacent to the sub-pixel 22, and covers at least part of the groove wall of the first sub-groove 252.

In an embodiment, a sub-encapsulation part 24 corresponding to at least one sub-pixel 22 adjacent to the groove 25 further covers the groove wall of the first sub-groove 252 adjacent to the sub-pixel 22 and covers part of a bottom wall of the first sub-groove 252.

In this way, for a sub-pixel 22, the sub-encapsulation part 24 may form three encapsulation rings, thereby improving the encapsulation performance of the sub-encapsulation part 24. One encapsulation ring is formed in the first sub-groove 252, another encapsulation ring is formed on the first recess 23b, and another encapsulation ring is formed on the second recess 23c.

In one of the embodiments, the sub-encapsulation parts 24 at two sides of the groove 25 both extend to cover the same groove 25. In this way, the groove 25 may achieve an enhanced encapsulation for the sub-encapsulation parts 24 at the two sides of the groove 25, which helps in improving the encapsulation reliability of the display panel 20.

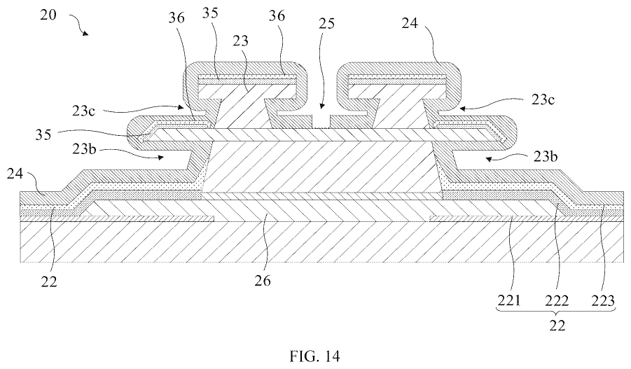

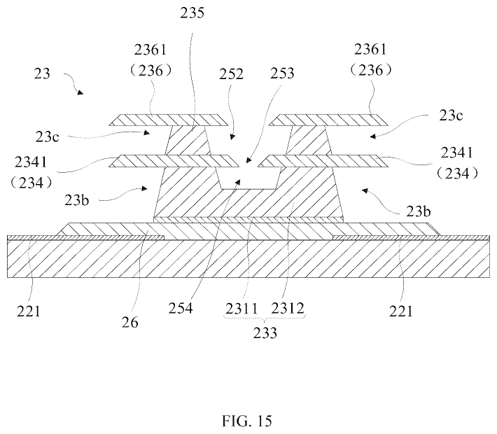

In one of the embodiments, referring to FIG. 14 and FIG. 15, the groove 25 further penetrates through the first blocking part 234 in the thickness direction of the substrate 21.

In an embodiment, the groove 25 further penetrates through at least part of the first partition body 233 in the thickness direction of the substrate 21. In this way, a depth of the groove 25 may be greater, and space for attaching the sub-encapsulation part 24 may be larger, which helps improving the encapsulation reliability of the sub-encapsulation part 24.

In one of the embodiments, the groove 25 further includes a sub-opening 253 and a second sub-groove 254. The sub-opening 253 penetrates through the first blocking part 234 in the thickness direction of the substrate 21, and the second sub-groove 254 is formed on the top side of the first partition body 233 away from the substrate 21. The first partition body 233, the first blocking part 234, the second partition body 235, and the second blocking part 236 define the groove 25. The first sub-groove 252, the sub-opening 253, and the second sub-groove 254 define the groove cavity 25b.

In this way, a coverage area of the sub-encapsulation part 24 inside the groove 25 is increased, and the encapsulation reliability of the sub-encapsulation part 24 is improved.

In one of the embodiments, a dimension of the sub-opening 253 along the first direction X is less than a dimension of the second sub-groove 254 along the first direction X.

In this way, the sub-encapsulation part 24 forms multiple encapsulation rings inside the groove 25, thus further improving the encapsulation reliability of the sub-encapsulation part 24.

In one of the embodiments, a sub-encapsulation part 24 corresponding to at least one sub-pixel 22 adjacent to the groove 25 further covers a side, proximate to the groove 25, of the second blocking part 236 adjacent to the sub-pixel 22, covers a groove wall of the first sub-groove 252 adjacent to the sub-pixel 22, and covers a side, proximate to the groove 25, of the first blocking part 234 adjacent to the sub-pixel 22, and covers at least part of a groove wall of the second sub-groove 254.

In this way, for one sub-pixel 22, the sub-encapsulation part 24 may form four encapsulation rings, thereby improving the encapsulation performance of the sub-encapsulation part 24. One encapsulation ring is formed inside the second sub-groove 254, a second encapsulation ring is formed inside the first sub-groove 252, a third encapsulation ring is formed inside the first recess 23b, and a fourth encapsulation ring is formed inside the second recess 23c. Further, in this embodiment, a cavity between the top of the isolating structure 23 and the sub-encapsulation part 24 may be further eliminated, thereby reducing a risk that a peeling occurs between the sub-encapsulation part 24 and the isolating structure 23, and improving the encapsulation performance of the sub-encapsulation part 24.

In a specific embodiment, as shown in FIG. 15, the first blocking part 234 includes two first sub-blocking parts 2341 arranged and spaced apart along the first direction X. A sub-opening 253 is formed between the two first sub-blocking parts 2341. The first partition body 233, the second partition body 235, the two first sub-blocking parts 2341 and the two second sub-blocking parts 2361 define the groove 25.

In an example, the sub-encapsulation part 24 corresponding to the at least one sub-pixel 22 adjacent to the groove 25 further covers a side of the second sub-blocking part 2361 proximate to the groove 25, a groove wall of the first sub-groove 252, a side of the first sub-blocking part 2341 proximate to the groove 25, and at least part of the groove wall of the second sub-groove 254.

In an example, the second sub-groove 254 does not penetrate through the first partition body 233 in the thickness direction of substrate 21. In this way, the first partition body 233 is not divided, so that the first partition body 233 can function as a current conductor.

In one of the embodiments, as shown in FIG. 14, the sub-pixel 22 includes the first electrode 221, a light-emitting functional part 222, and a second electrode 223, which are arranged and stacked in a direction away from the substrate 21. The second electrode 223 of the sub-pixel 22 is electrically connected to the isolating structure 23.

In this way, it is convenient to connect the second electrode 223 of the sub-pixel 22 to the pixel driving circuit through the isolating structure 23, so that an arrangement of the wiring of the display area is optimized.

It should be noted that, the first electrode 221 may be an anode, and the second electrode 223 may be a cathode. Both the first electrode 221 and the second electrode 223 are electrically connected to the pixel driving circuit. If the first electrode 221 is a cathode, then the isolating structure 23 transmits a VSS signal. If first electrode 221 is an anode, then the isolating structure 23 transmits a VDD signal.

It may be understood that the light-emitting functional part 222 includes at least an emission layer (EML). In addition, the light-emitting functional part 222 may further include one or more of a hole injection layer (HIL), a hole transport layer (HTL), an electronic injection layer (EIL), an electronic transport layer (ETL), a hole block layer (HBL), and an electronic block layer (EBL). Alternatively, the light-emitting functional part 222 may be a laminated light emitting layer, namely, may include at least two light emitting layers and a charge generation layer (CGL) located between adjacent light emitting layers.

In one of the embodiments, the first partition body 233 includes at least one metal layer. The second electrode 223 of the sub-pixel 22 is electrically connected to the first partition body 233. In an embodiment, the partition body 231 includes a metal layer. Further, the material of the partition body 231 includes at least one of a metal or a metal oxide. For example, the metal may be silver, copper, titanium, aluminum, or the like, and the metal oxide may be tin oxide, zinc oxide, cadmium oxide, indium oxide, indium tin oxide, zinc oxide indium, zinc oxide crop, zinc aluminum oxide, titanium tantalum oxide, or the like.

In one of the embodiments, the first partition body 233 includes a first metal layer 2311 and a second metal layer 2312, which are arranged and stacked in a direction away from the substrate 21. The resistivity of the second metal layer 2312 is less than that of the first metal layer 2311. The second electrode 223 of the sub-pixel 22 is in direct contact with the second metal layer 2312.

In this way, on the one hand, the electrical contact resistance between the isolating structure 23 and the second electrode 223 is reduced, and on the other hand, the resistance of the isolating structure 23 is reduced, thereby reducing the power consumption of the display panel 20.

In an example, a material of the first metal layer 2311 may be Mo, and a material of the second metal layer 2312 may be A1. A material of the sub-blocking part 2321 may be Ti.

In one of the embodiments, a material of the second partition body 235 is the same as a material of the first partition body 233. A material of the second sub-blocking part 2361 may be the same as that of the first sub-blocking part 2341.

In one of the embodiments, the second partition body 235 and the second blocking part 236 are an integral structure, and a material of the second partition body 235 and second blocking part 236 is organic or inorganic material. In this way, the difficulty in preparing the second partition body 235 and the second blocking part 236 may be reduced.

In one of the embodiments, as shown in FIG. 2D, the display panel 20 further includes a first encapsulation layer 27 and a second encapsulation layer 28. The first encapsulation layer 27 covers at least one side, away from the substrate 21, of each of the plurality of sub-encapsulation parts 24. The second encapsulation layer 28 covers one side of the first encapsulation layer 27 away from the substrate 21. The first encapsulation layer 27 is an organic film layer, and the second encapsulation layer 28 is an inorganic film layer, such that the encapsulation performance of the display panel 20 may be improved.

In one of the embodiments, the second partition body 235 and the second blocking part 236 shown in FIG. 13 may be prepared through the following steps S10 to S30.

In step S10, negative photoresist is formed on the first blocking part 234.

In step S20, a hardening processing is performed on a local area of the negative photoresist. Specifically, a medicament may be used to harden part of the negative photoresist, making it difficult to develop and etch the part of the negative photoresist.

In step S30, the negative photoresist is etched to form the second partition body 235 and the second blocking part 236. Because the etching speed of the processed negative photoresist is relatively low, and the etching speed of the unprocessed negative photoresist is relatively high, the structure shown in FIG. 13 may be formed.

In a third aspect, as shown in FIG. 2A and FIG. 10, an embodiment of this application provides a display panel 20. The display panel 20 may be an OLED display panel 20 or a QDLED display panel 20.

The display panel 20 includes a substrate 21, a plurality of sub-pixels 22, an isolating structure 23, and a plurality of sub-encapsulation parts 24.

Specifically, the substrate 21 may be an array substrate. The multiple sub-pixels 22 are arranged on the substrate 21 at intervals. The isolating structure 23 is disposed on the substrate 21. The isolating structure 23 is disposed between at least some of adjacent sub-pixels 22. The multiple sub-encapsulation parts 24 are arranged on sides of the corresponding sub-pixels 22 away from the substrate 21, respectively.

As shown in FIG. 10, a first undercut part 23d is arranged at a side of the isolating structure 23 proximate to the adjacent sub-pixel 22, to isolate the two adjacent sub-pixels 22. A second undercut part 23e is further arranged at the side of the isolating structure 23 and is arranged apart from the first undercut part 23d. The sub-encapsulation part 24 corresponding to the sub-pixel 22 adjacent to the isolating structure 23 also extends over wall surfaces of the first undercut part 23d and second undercut part 23e to form a continuous film structure.

According to the display panel 20 provided in this embodiment of this application, the first undercut part 23d and the second undercut part 23e are arranged on the isolating structure 23, and the sub-encapsulation part 24 covers the corresponding sub-pixel 22, the first undercut part 23d, and the second undercut part 23e. In this way, on one hand, a coverage area of the sub-encapsulation part 24 on the isolating structure 23 is increased, so that a peeling path of the sub-encapsulation part 24 is prolonged, and the encapsulation performance of the sub-encapsulation part 24 is improved. On the other hand, because the sub-encapsulation part 24 covers over the second undercut part 23e, even if the peeling occurs, the second undercut part 23e may play a function of blocking, thereby increasing the difficulty of peeling occurring to the sub-encapsulation part 24, reducing a risk that the peeling occurs between the sub-encapsulation part 24 and the isolating structure 23, and improving the encapsulation performance of the sub-encapsulation part 24.

In one of the embodiments, an end surface of the first undercut part 23d proximate to the substrate 21 is defined as a first bottom, an end surface of the first undercut part 23d away from the substrate 21 is defined as a first top, and an outer profile of an orthographic projection of the first top projected on the substrate 21 is located at a periphery of an outer profile of an orthographic projection of the first bottom projected on the substrate 21.

An end surface of the second undercut part 23e proximate to the substrate 21 is defined as a second bottom, an end surface of the second undercut part 23e away from the substrate 21 is defined as a second top, and an outer profile of an orthographic projection of the second top projected on the substrate 21 is located at a periphery of an outer profile of an orthographic projection of the second bottom projected on the substrate 21.

It should be noted that an undercut part in this embodiment of this application is an undercut structure known to the skilled in the art.

In one of the embodiments, as shown in FIG. 2A, the first undercut part 23d and the second undercut part 23e are disposed side by side between two adjacent sub-pixels 22. In an example, one first undercut part 23d and one second undercut part 23e are arranged between two adjacent sub-pixels 22, and the first undercut part 23d and the second undercut part 23e correspond to the same sub-pixel 22. In this way, only the sub-encapsulation part 24 corresponding to the sub-pixel 22 may extend to cover the wall surfaces of the first undercut part 23d and the second undercut part 23e.

In an embodiment, two first undercut parts 23d and at least one second undercut part 23e are arranged between two adjacent sub-pixels 22, and the at least one second undercut part 23e is disposed between the two first undercut parts 23d. In this way, the two sub-encapsulation parts 24 corresponding to the two sub-pixels 22 each may extend to cover the wall of a corresponding first undercut part 23d and the wall of second undercut part 23e.

In an example, as shown in FIG. 13, a first recess 23b is disposed on a side of the isolating structure 23 proximate to the adjacent sub-pixel 22, and the first recess 23b defines a first undercut part 23d. At least one groove 25 is formed on the top side of the isolating structure 23 away from the substrate 21, and the groove 25 has a groove cavity 25b proximate to the substrate 21 and an opening 25a away from the substrate 21. The orthographic projection of the opening 25a projected on the substrate 21 is within the orthographic projection of the groove cavity 25b projected on the substrate 21. The second recess 23c defines a second undercut part 23e.

In this way, on one hand, compared with the related technology, in this embodiment of this application, a coverage area of the sub-encapsulation part 24 on the isolating structure 23 is increased, thereby extending a peeling path from an end coverage location of the sub-encapsulation part 24 to a surface of the sub-pixel 22, and improving the encapsulation performance of the sub-encapsulation part 24.

On the other hand, when the light-emitting material and the electrode material of the sub-pixel 22 are evaporated, the light-emitting material and the electrode material cannot cover the groove wall of the groove 25. However, the sub-encapsulation part 24 extends to the groove wall of the groove 25, that is, the sub-encapsulation part 24 is in direct contact with the groove wall of the groove 25, therefore the top of the isolating structure 23 is completely encapsulated. In a subsequent etching process, the light-emitting material and the electrode material on the top of the isolating structure 23 are retained. Therefore, compared with the related technology, in this embodiment of this application, a cavity between the sub-encapsulation part 24 and the top of the isolating structure 23 is eliminated, thereby reducing a risk of peeling occurring between the sub-encapsulation part 24 and the isolating structure 23, and improving the encapsulation performance of the sub-encapsulation part 24.

In still another aspect, because the sub-encapsulation part 24 extends to the groove wall of the groove 25, even if the peeling occurs, the groove wall of the groove 25 can play a function of blocking, so as to slow down the peeling of the sub-encapsulation part 24 away an inner side of the groove 25, thereby protecting the sub-encapsulation part 24, reducing a risk that the peeling occurs between the sub-encapsulation part 24 and the isolating structure 23, and improving the encapsulation performance of the sub-encapsulation part 24.

In another aspect, for a sub-pixel 22, the sub-encapsulation part 24 may form two encapsulation rings, thereby improving the encapsulation performance of the sub-encapsulation part 24. One encapsulation ring is formed at the first undercut part 23d, and another encapsulation ring is formed at the second undercut part 23e.

In another aspect, the sub-encapsulation part 24 covers a side surface of the isolating structure 23 proximate to the sub-pixel 22, that is, the sub-encapsulation part 24 is in direct contact with the side surface of the isolating structure 23 proximate to the sub-pixel 22. In this way, an encapsulation function may be achieved, and the encapsulation reliability of the sub-encapsulation part 24 can be improved.

It should be noted that the configuration method of the groove 25 in this embodiment may be the same as that of the groove 25 in the display panel 20 in the first aspect and will not be described hereinafter again.

In one of the embodiments, referring to FIG. 10, the first undercut part 23d and the second undercut part 23e are arranged in a direction away from the substrate 21 in sequence.

Specifically, the isolating structure 23 defines multiple isolation openings 23a. and multiple sub-pixels 22 are arranged in the multiple isolation openings 23a, respectively. The isolating structure 23 includes the first partition body 233, the first blocking part 234, the second partition body 235, and the second blocking part 236, which are arranged and stacked in a direction away from substrate 21. The first blocking part 234 extends in a direction towards the isolation opening 23a to protrude from the side surface of the first partition body 233. The second blocking part 236 extends in a direction towards the isolation opening 23a to protrude from the side surface of the second partition body 235. The first blocking part 234 and the first partition body 233 define the first undercut part 23d. The second blocking part 236 and the second partition body 235 define the second undercut part 23e.

It should be noted that the groove 25 may also be formed on the isolating structure 23 in this embodiment. The configuration method of the groove 25 may be the same as that of the display panel 20 in the second aspect, and will not be described hereinafter again.

In one of the embodiments, as shown in FIG. 2D, the display panel 20 further includes a first encapsulation layer 27 and a second encapsulation layer 28. The first encapsulation layer 27 covers at least one side, away from the substrate 21, of each of the plurality of sub-encapsulation parts 24. The second encapsulation layer 28 covers one side of the first encapsulation layer 27 away from the substrate 21. The first encapsulation layer 27 is an organic film layer, and the second encapsulation layer 28 is an inorganic film layer, such that the encapsulation performance of the display panel 20 may be improved.

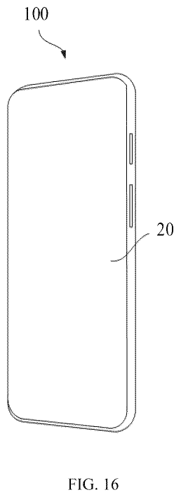

In a fourth aspect, as shown in FIG. 16, an embodiment of this application provides a display device 100. The display device 100 includes the display panel 20 in any one of the first aspect, the second aspect, or the third aspect.

The display device 100 may be a notebook computer, a mobile phone, a wireless apparatus, a personal digital assistant (PDA), a handheld or portable computer, a GPS receiver/navigator, a camera, an MP4 video player, a camera, a game console, a watch, a clock, a calculator, a television monitor, a flat panel display, a computer monitor, a vehicle display (for example, an odometer display), a navigator, a cabin controller and/or a display, a camera-image display (for example, a display of a rear-view camera in a vehicle), an electronic photo, an electronic board or an indicator, a projector, or the like.

The display device 100 provided in this embodiment of this application can improve the encapsulation performance of the sub-encapsulation part 24, thereby improving the reliability of the display device 100.

What is claimed is:

1. A display panel, comprising:
a substrate;
a plurality of sub-pixels arranged on the substrate at intervals;
an isolating structure, disposed between at least some of adjacent sub-pixels; at least one groove being formed on a top side of the isolating structure away from the substrate, and each groove having a groove cavity proximate to the substrate and an opening away from the substrate; an orthographic projection of the opening projected on the substrate being within an orthographic projection of the groove cavity projected on the substrate; and
a plurality of sub-encapsulation parts arranged on sides of corresponding sub-pixels away from the substrate, respectively; and each sub-encapsulation part corresponding to at least one sub-pixel adjacent to each groove covering a side surface of the isolating structure proximate to the at least one sub-pixel, a top side of the isolating structure away from the substrate, and at least part of a groove wall of the groove.

2. The display panel according to claim 1, wherein the isolating structure comprises a partition body and a blocking part, which are arranged and stacked on the substrate; the blocking part extends in a direction towards a corresponding sub-pixel to protrude from a side surface of the partition body proximate to the corresponding sub-pixel; the partition body and the blocking part define each groove;
optionally, the opening penetrates through the blocking part in a thickness direction of the substrate, a sub-groove is formed on a top side of the partition body away from the substrate, and the sub-groove defines the groove cavity;
optionally, a dimension (L) of the opening along a first direction (X) is less than a dimension (W) of the sub-groove along the first direction (X), and the first direction (X) is perpendicular to a thickness direction of the substrate and an extension direction of the groove;
optionally, the sub-groove penetrates through the partition body in the thickness direction of the substrate;
optionally, the sub-groove is configured as a light transmitting hole;
optionally, at least one groove is formed on the isolating structure between two adjacent sub-pixels; and
optionally, a light-emitting material layer and an electrode material layer are arranged and stacked in sequence on a top side of the first blocking part away from the substrate, and the sub-encapsulation part corresponding to at least one sub-pixel adjacent to the groove further covers a top surface of the electrode material layer, a side surface of the electrode material layer, and a side surface of the light-emitting material layer.

3. The display panel according to claim 2, wherein one groove is formed between two adjacent sub-pixels; and sub-encapsulation parts corresponding to the two adjacent sub-pixels extend to the same groove;
optionally, each sub-encapsulation part corresponding to a sub-pixel adjacent to the groove further covers a side, proximate to the groove, of the blocking part adjacent to the sub-pixel; or the sub-encapsulation part corresponding to the sub-pixel adjacent to the groove further covers one groove wall of the sub-groove adjacent to the sub-pixel.

4. The display panel according to claim 2, wherein two grooves are formed and arranged in parallel between two adjacent sub-pixels;
sub-encapsulation parts corresponding to two adjacent sub-pixels extend and cover the grooves adjacent to the corresponding sub-pixels respectively;
optionally, each sub-encapsulation part corresponding to a sub-pixel adjacent to each groove further covers a side, proximate to the groove, of the blocking part adjacent to the sub-pixel;
optionally, the sub-encapsulation part corresponding to the sub-pixel adjacent to each groove further covers one groove wall of the sub-groove adjacent to the sub-pixel; or the sub-encapsulation part corresponding to the sub-pixel adjacent to each groove further covers all groove walls of the sub-groove.

5. The display panel according to claim 2, wherein each sub-pixel comprises a first electrode, a light-emitting functional part, and a second electrode, which are arranged and stacked in a direction away from the substrate; the second electrode of the sub-pixel is electrically connected to the isolating structure;
optionally, the partition body comprises at least one metal layer, and the second electrode of the sub-pixel is electrically connected to the partition body.

6. The display panel according to claim 2, wherein each sub-pixel comprises a first electrode, a light-emitting functional part, and a second electrode, which are arranged and stacked in a direction away from the substrate; the second electrode of the sub-pixel is electrically connected to the isolating structure;
optionally, the partition body comprises a first metal layer and a second metal layer, which are arranged and stacked in a direction away from the substrate; a resistivity of the second metal layer is less than that of the first metal layer; and the second electrode of the sub-pixel is in direct contact with the second metal layer.

7. The display panel according to claim 1, wherein the isolating structure defines multiple isolation openings, and a sub-pixel is correspondingly arranged in each isolation opening; at least one groove is arranged to surround at least part of a periphery of each isolation opening;
optionally, the groove is arranged to surround at least part of the periphery of each isolation opening;
optionally, each groove comprises multiple groove sections, and the multiple groove sections are arranged to surround the periphery of each isolation opening;
optionally, the multiple groove sections are evenly arranged to surround the periphery of each isolation opening.

8. The display panel according to claim 1, wherein the isolating structure defines multiple isolation openings, and a sub-pixel is correspondingly arranged in each isolation opening; at least one groove is arranged to surround at least part of a periphery of each isolation opening;
optionally, each groove is arranged to surround a whole periphery of each isolation opening; or optionally, an orthographic projection of each groove surrounding each isolation opening, which is projected on the substrate, has a closed shape.

9. The display panel according to claim 1, wherein the isolating structure defines multiple isolation openings, and a sub-pixel is correspondingly arranged in each isolation opening; at least one groove is arranged to surround at least part of a periphery of each isolation opening;
optionally, each sub-encapsulation part is an inorganic film layer; and
optionally, the display panel further comprises a first encapsulation layer and a second encapsulation layer; the first encapsulation layer covers at least a side of each of the plurality of sub-encapsulation parts away from the substrate; the second encapsulation layer covers one side of the first encapsulation layer away from the substrate; the first encapsulation layer is an organic film layer; and the second encapsulation layer is an inorganic film layer.

10. A display panel, comprising:
a substrate;
a plurality of sub-pixels arranged on the substrate at intervals;
an isolating structure disposed between at least some of adjacent sub-pixels; a first recess and a second recess being formed and spaced apart in a direction away from the substrate on a side surface of the isolating structure proximate to a sub-pixel; and
a plurality of sub-encapsulation parts arranged on sides of corresponding sub-pixels away from the substrate, respectively; and each sub-encapsulation part being configured as a continuous film structure that covers the corresponding sub-pixel, the first recess, and the second recess.

11. The display panel according to claim 10, wherein the isolating structure defines multiple isolation openings, and the multiple sub-pixels are arranged in the multiple isolation openings, respectively;
the isolating structure comprises a first partition body, a first blocking part, a second partition body, and a second blocking part, which are arranged and stacked in a direction away from the substrate; the first blocking part extends in a direction towards a corresponding isolation opening to protrude from a side surface of the first blocking part; the second blocking part extends in a direction towards the corresponding isolation opening to protrude from a side surface of the second partition body; and
the first blocking part, the first partition body, and the substrate define the first recess; and the second blocking part, the second partition body, and the first blocking part define the second recess; and
optionally, a light-emitting material layer and an electrode material layer are arranged and stacked in sequence on a top side of the first blocking part away from the substrate, and the sub-encapsulation part further covers a top surface of the electrode material layer, a side surface of the electrode material layer, and a side surface of the light-emitting material layer.

12. The display panel according to claim 11, wherein at least one groove is formed on a top side of the isolating structure away from the substrate, and each groove has a groove cavity proximate to the substrate and an opening away from the substrate; an orthographic projection of the opening projected on the substrate is within an orthographic projection of the groove cavity projected on the substrate; and
each sub-encapsulation part corresponding to at least one sub-pixel adjacent to each groove further covers a side surface of the isolating structure proximate to a corresponding sub-pixel, a top side of the isolating structure away from the substrate, and at least part of a groove wall of the groove; and
optionally, the light-emitting material layer and the electrode material layer are arranged and stacked in sequence on a top side of the second blocking part away from the substrate, and the sub-encapsulation part further covers a top surface of the electrode material layer, a side surface of the electrode material layer, and a side surface of the light-emitting material layer.

13. The display panel according to claim 12, wherein each groove penetrates through the second blocking part and at least part of the second partition body in a thickness direction of the substrate;
optionally, the groove penetrates through the whole second partition body in a thickness direction of the substrate;
optionally, the groove is configured as a light transmitting hole;
optionally, the opening penetrates through the second blocking part in the thickness direction of the substrate; the groove comprises a first sub-groove, and the first sub-groove penetrates through the second partition body in the thickness direction of the substrate.

14. The display panel according to claim 12, wherein each groove penetrates through the second blocking part and at least part of the second partition body in a thickness direction of the substrate;
optionally, the first blocking part, the second partition body, and the second blocking part define the groove, and the first sub-groove defines the groove cavity;
optionally, a dimension of the opening along a first direction (X) is less than a dimension of the first sub-groove along the first direction (X), and the first direction (X) is perpendicular to the thickness direction of the substrate and perpendicular to an extension direction of the groove;
optionally, the sub-encapsulation part corresponding to the at least one sub-pixel adjacent to the groove further covers a side, proximate to the groove, of the second blocking part adjacent to the sub-pixel, and covers at least part of a groove wall of the first sub-groove; and
optionally, at least one groove is formed on the isolating structure between two adjacent sub-pixel.

15. The display panel according to claim 13, wherein the groove further penetrates through the first blocking part in the thickness direction of the substrate;
optionally, the groove further penetrates through at least part of the first partition body in the thickness direction of the substrate; and
optionally, the groove further comprises a sub-opening and a second sub-groove; the sub-opening penetrates through the first blocking part in the thickness direction of the substrate, and the second sub-groove is formed on a top side of the first partition body away from the substrate; and
the first partition body, the first blocking part, the second partition body, and the second blocking part define the groove; the first sub-groove, the sub-opening, and the second sub-groove define the groove cavity;
optionally, a dimension of the sub-opening along the first direction X is less than a dimension of the second sub-groove along the first direction X; and
optionally, the sub-encapsulation part corresponding to at least one sub-pixel adjacent to the groove further covers a side, proximate to the groove, of the second blocking part adjacent to the sub-pixel, covers a groove wall of the first sub-groove adjacent to the sub-pixel, and covers a side, proximate to the groove, of the first blocking part adjacent to the sub-pixel, and covers at least part of a groove wall of the second sub-groove.

16. The display panel according to claim 11, wherein sub-pixel comprises a first electrode, a light-emitting functional part, and a second electrode, which are arranged and stacked in a direction away from the substrate; the second electrode of the sub-pixel is electrically connected to the isolating structure;
optionally, the first partition body comprises at least one metal layer; the second electrode of the sub-pixel is electrically connected to the first partition body;
optionally, the partition body comprises a first metal layer and a second metal layer, which are arranged and stacked in a direction away from the substrate; a resistivity of the second metal layer is less than that of the first metal layer; the second electrode of the sub-pixel is in direct contact with the second metal layer;
optionally, the second partition body and the second blocking part are an integral structure, and a material of the second partition body and a material of the second blocking part are organic or inorganic material;
optionally, the sub-encapsulation part is an inorganic film layer; and
optionally, the display panel further comprises a first encapsulation layer and a second encapsulation layer; the first encapsulation layer covers at least a side of each sub-encapsulation part away from the substrate; the second encapsulation layer covers a side of the first encapsulation layer away from the substrate; the first encapsulation layer is an organic film layer, and the second encapsulation layer is an inorganic film layer.

17. A display panel, comprising:
a substrate;
a plurality of sub-pixels arranged on the substrate at intervals;
an isolating structure arranged on the substrate and disposed between at least some of adjacent sub-pixels; a first undercut part being arranged at a side of the isolating structure proximate to an adjacent sub-pixel, to isolate the two adjacent sub-pixels; a second undercut part being further arranged at the side of the isolating structure and arranged apart from the first undercut part; and
a plurality of sub-encapsulation parts arranged on sides of corresponding sub-pixels away from the substrate, respectively; each sub-encapsulation part corresponding to a sub-pixel adjacent to the isolating structure also extending over a wall surface of the first undercut part and a wall surface of the second undercut part to form a continuous film structure.

18. The display panel according to claim 17, wherein an end surface of the first undercut part proximate to the substrate is defined as a first bottom, and an end surface of the first undercut part away from the substrate is defined as a first top and an outer profile of an orthographic projection of the first top projected on the substrate is located at a periphery of an outer profile of an orthographic projection of the first bottom projected on the substrate; and
an end surface of the second undercut part proximate to the substrate is defined as a second bottom, and an end surface of the second undercut part away from the substrate is defined as a second top, and an outer profile of an orthographic projection of the second top projected on the substrate is located at a periphery of an outer profile of an orthographic projection of the second bottom projected on the substrate.

19. The display panel according to claim 17, wherein the first undercut part and the second undercut part are arranged in a direction away from the substrate in sequence;
optionally, the isolating structure defines multiple isolation openings; and the multiple sub-pixels are arranged in the multiple isolation openings, respectively;
the isolating structure comprises a first partition body, a first blocking part, a second partition body, and a second blocking part, which are arranged and stacked in a direction away from substrate; the first blocking part extends in a direction towards a corresponding isolation opening to protrude from a side surface of the first partition body; the second blocking part extends in a direction towards the corresponding isolation opening to protrude from a side surface of the second partition body; and
the first blocking part and the first partition body define the first undercut part, and the second blocking part and the second partition body define the second undercut part.

20. The display panel according to claim 17, wherein the first undercut part and the second undercut part are disposed side by side between two adjacent sub-pixels;
optionally, two first undercut parts and at least one second undercut part are arranged between two adjacent sub-pixel, and the at least one second undercut part is disposed between the two first undercut parts;
optionally, a first recess is disposed on a side of the isolating structure proximate to an adjacent sub-pixel, and the first recess defines the first undercut part;
at least one groove is formed on a top side of the isolating structure away from the substrate, and the groove has a groove cavity proximate to the substrate and an opening away from the substrate; an orthographic projection of the opening projected on the substrate is within an orthographic projection of the groove cavity projected on the substrate; and the second recess defines a second undercut part;
optionally, the sub-encapsulation part is an inorganic film layer; and
optionally, the display panel further comprises a first encapsulation layer and a second encapsulation layer; the first encapsulation layer covers at least a side of each sub-encapsulation part away from the substrate; the second encapsulation layer covers one side of the first encapsulation layer away from the substrate; the first encapsulation layer is an organic film layer; and the second encapsulation layer is an inorganic film layer.
